(19) United States
(12) Patent Application Publication
(10) Pub. No.: US 2025/0391775 A1
(43) Pub. Date: Dec. 25, 2025

(54) INTEGRATED CIRCUIT DIE STITCHING USING JUMPER DIE

(71) Applicant: Zero ASIC Corporation, Lexington, MA (US)

(72) Inventors: Andreas Olofsson, Lexington, MA (US); Lizabeth Keser, San Diego, CA (US)

(21) Appl. No.: 18/753,356

(22) Filed: Jun. 25, 2024

(51) Int. Cl. H01L 23/538; H01L 23/00; H01L 23/373; H01L 23/498; H01L 25/065

(52) U.S. Cl. CPC H01L 23/5381; H01L 23/3735; H01L 23/49816; H01L 24/05; H01L 24/13; H01L 24/97; H01L 25/0655; H01L 2224/05009; H01L 2224/05025; H01L 2224/13009; H01L 2224/13025; H01L 2224/97; H01L 2924/1431; H01L 2924/1434; H01L 2924/15311; H01L 2924/182

(57) ABSTRACT

A technique for interconnecting integrated circuit die of a substrate uses a jumper die that is vertically attached to adjacent integrated circuit die thereby coupling the adjacent die across a scribe line adjacent to the integrated circuit die. In an embodiment, an integrated circuit product includes a first integrated circuit die having a first die interface, a second integrated circuit die having a second die interface, a scribe line of a first surface of a semiconductor substrate, and a jumper die coupled to the first die interface and coupled to the second die interface. The jumper die spans the scribe line. A first portion of the jumper die is stacked with a first portion of the first integrated circuit die and a second portion of the jumper die is stacked with a first portion of the second integrated circuit die.

### BACKGROUND

### Field of the Invention

This invention relates to integrated circuit devices and more particularly to manufacture and packaging of integrated circuit devices.

### Description of the Related Art

In general, semiconductor manufacturing equipment processes semiconductor wafers by dividing the wafers into a grid of integrated circuit die that are patterned simultaneously using a reticle. As integrated circuit designs increase in complexity, an integrated circuit design may exceed a maximum size of an integrated circuit die that can be fabricated using current lithography techniques (i.e., exceed a reticle limit). Advances in manufacturing technology that shrink the critical dimension of a manufacturing process may increase the number of integrated circuit die manufactured using one reticle. These integrated circuit die may be interconnected using reticle stitching techniques to achieve desired functionality and performance.

Conventional reticle stitching techniques include forming interconnect lines that cross reticle boundaries and traverse a stitch region of an integrated circuit design. Those techniques require overlapping images of the reticle, oversized structures, or using multiple reticles to generate offset images in the stitch region. Use of an additional reticle set substantially increases manufacturing cost, impacts yield, and may require joint development with a target foundry. Typical 2.5D packaging techniques use an interposer to facilitate connections between different components or technologies that might not naturally interface with each other due to differences in form factor, electrical specifications, or other factors. Use of an interposer provides an electrical interface routing between one socket or connection to another and may spread connections to a wider pitch or to reroute connections. An interposer substantially increases the cost of manufacturing a related integrated circuit product. Accordingly, improved techniques for reticle stitching or otherwise coupling multiple die of a multi-die product are desired.

### SUMMARY OF EMBODIMENTS OF THE INVENTION

In an embodiment, an integrated circuit product includes a first integrated circuit die having a first die interface, a second integrated circuit die having a second die interface, a scribe line of a first surface of a semiconductor substrate, and a jumper die coupled to the first die interface and coupled to the second die interface. The first integrated circuit die and the second integrated circuit die are formed using the semiconductor substrate. The first integrated circuit die is adjacent to the scribe line and the second integrated circuit die is adjacent to the scribe line. The jumper die spans the scribe line. A first portion of the jumper die is stacked with a first portion of the first integrated circuit die and a second portion of the jumper die is stacked with a first portion of the second integrated circuit die. The scribe line may be an inter-reticle scribe line. The scribe line may be an intra-reticle scribe line. The integrated circuit product may include an additional die coupled to the first integrated circuit die and stacked with the first integrated circuit die. The additional die may be laterally adjacent to the jumper die with respect to the first surface of the semiconductor substrate. A space between the additional die and the jumper die may have the same width as the scribe line. A first conductive pad of a front side of the jumper die is connected to a corresponding conductive pad of a front side of the first integrated circuit die vertically with respect the front side of the first integrated circuit die and the front side of the jumper die using a microbump or a hybrid bond. The first integrated circuit die may be disposed diagonally opposite to the second integrated circuit die.

In at least one embodiment, an integrated circuit product includes a jumper die comprising a first jumper die interface, a second jumper die interface, and a lateral interconnect structure coupled between the first jumper die interface and the second jumper die interface. The jumper die may be configured to transmit a signal received from a first integrated circuit die via the first jumper die interface to a second integrated circuit die via the second jumper die interface across a scribe line of a semiconductor substrate. The integrated circuit product may include a first integrated circuit die, and a second integrated circuit die. The first integrated circuit die and the second integrated circuit die may be formed using a semiconductor substrate. The jumper die may be stacked with a first corresponding die interface of the first integrated circuit die and stacked with a second corresponding die interface of the second integrated circuit die and the jumper die may span a scribe line of a first surface of the semiconductor substrate. The first jumper die interface includes a first conductive pad of a front side of the jumper die. The first conductive pad is connected to a corresponding conductive pad of a front side of the first integrated circuit die vertically with respect the front side of the first integrated circuit die using a microbump or a hybrid bond. The lateral interconnect structure may include an active circuit. The jumper die may include power supply terminals configured to provide power to the active circuit. The lateral interconnect structure may be passive interconnect.

In at least one embodiment, a method for manufacturing a three-dimensional integrated circuit product includes vertically attaching a jumper die to a first die interface of a first integrated circuit die and a second die interface of a second integrated circuit die. The first integrated circuit die and the second integrated circuit die are formed using a semiconductor substrate. The first integrated circuit die is separated from the second integrated circuit die by a scribe line of a first surface of the semiconductor substrate. The jumper die spans the scribe line and overlaps a first portion of the first integrated circuit die and overlaps a second portion of the second integrated circuit die. The first integrated circuit die may be adjacent to or diagonally opposite to the second integrated circuit die. The method may include manufacturing the first integrated circuit die and the second integrated circuit die using a first semiconductor substrate and an image of a reticle. The scribe line may be an intra-reticle scribe line and the first integrated circuit die and the second integrated circuit die may correspond to different locations within the image of the reticle. Vertically attaching may include connecting vertically with respect a front side of the first integrated circuit die and a front side of the jumper die, a first conductive pad of the front side of the jumper die to a corresponding conductive pad of the front side of the first integrated circuit die, using a microbump or a hybrid bond.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a plan view of a semiconductor wafer including integrated circuit die.

FIG. 2 illustrates a cross-sectional view of a portion of an integrated circuit product including integrated circuit die coupled across a scribe line using a jumper die consistent with at least one embodiment of the invention.

FIG. 3 illustrates a plan view of a portion of a semiconductor substrate including an integrated circuit die coupled to an adjacent integrated circuit die across a scribe line using a jumper die consistent with at least one embodiment of the invention.

FIG. 4 illustrates a plan view of a portion of a semiconductor substrate including integrated circuit die coupled to an adjacent integrated circuit die across an intra-reticle scribe line using a jumper die consistent with at least one embodiment of the invention.

FIG. 5 illustrates a plan view of a portion of a semiconductor substrate including a four-way jumper die coupling adjacent integrated circuit die across intersecting scribe lines consistent with at least one embodiment of the invention.

FIG. 6 illustrates a plan view of a portion of a semiconductor substrate including a catercorner jumper die coupling diagonally opposite integrated circuit die across intersecting scribe lines consistent with at least one embodiment of the invention.

FIG. 7 illustrates a detailed cross-sectional view of a portion of a semiconductor substrate including integrated circuit die coupled across a scribe line using a jumper die including passive interconnect consistent with at least one embodiment of the invention.

FIG. 8 illustrates a detailed cross-sectional view of a portion of a semiconductor substrate including integrated circuit die coupled across a scribe line using a jumper die including active interconnect consistent with at least one embodiment of the invention.

FIG. 9 illustrates a detailed cross-sectional view of an integrated circuit product including integrated circuit die coupled across a scribe line using a jumper die consistent with at least one embodiment of the invention.

FIG. 10 illustrates a flow diagram for an exemplary integrated circuit die stitching process using a jumper die consistent with at least one embodiment of the invention.

FIG. 11 illustrates an alternate flow diagram for an exemplary integrated circuit die stitching process using a jumper die consistent with at least one embodiment of the invention.

The use of the same reference symbols in different drawings indicates similar or identical items.

### DETAILED DESCRIPTION

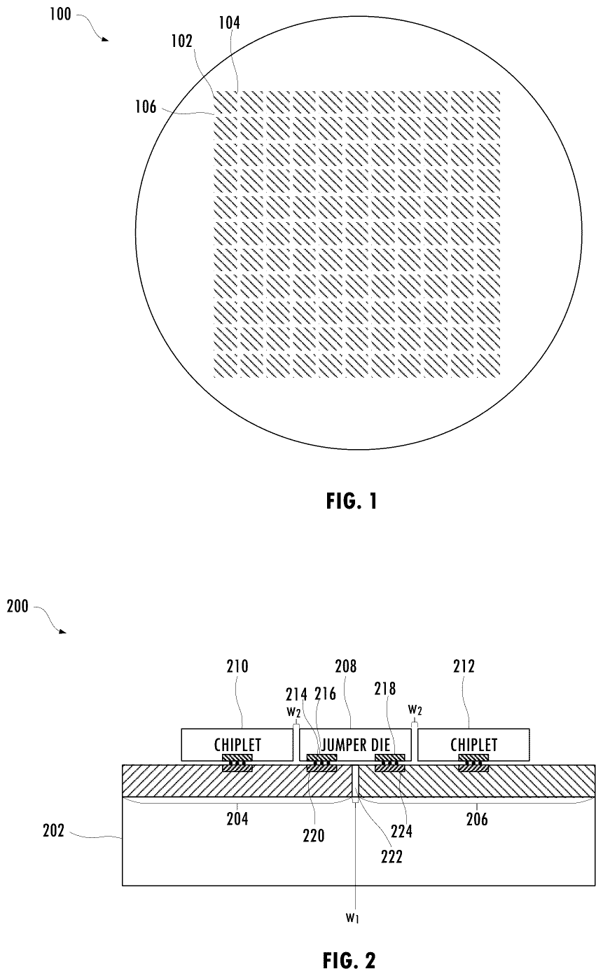

FIG. 1 illustrates wafer 100 used as a substrate to manufacture integrated circuit die. Wafer 100 is a thin slice of semiconductor material (i.e., a wafer, e.g., silicon, silicon dioxide, aluminum oxide, sapphire, germanium, gallium arsenide, an alloy of silicon and germanium, or indium phosphide) that is circular and has a predetermined diameter (e.g., 130 mm, 150 mm, 200 mm, or 300 mm). Any suitable integrated circuit fabrication process that includes lithography techniques for printing images of a reticle onto a semiconductor substrate is used to form a grid of integrated circuit die separated by vertical and horizontal scribe lines from patterned layers of dielectric and conductive materials. In general, lithography techniques use a set of reticles to expose ultraviolet radiation that generate specific patterns on the wafer. A reticle is a type of photomask (e.g., a glass plate with a pattern etched into an opaque surface) that includes a pattern image that lithography equipment steps and repeats in an array around the wafer to expose the entire wafer. Data for only part of the final exposed area is present on the wafer. A typical reticle has features that are larger than (e.g., 1.8, 2, 2.5, 4, 5 or 10 times) the size of a final image on the wafer, i.e., the features are reduced in scale on the wafer. In general, the maximum size an integrated circuit die can be printed with a lithography tool is referred to as the reticle limit. Integrated circuits that exceed the reticle limit can be formed by using the reticle to form multiple sub-fields and coupling those subfields using a technique called reticle stitching. As a result of the semiconductor fabrication process, wafer 100 includes an array of identical integrated circuit die separated by vertical and horizontal scribe lines. For example, integrated circuit die 102 is separated from adjacent integrated circuit die by vertical scribe line 104 and horizontal scribe line 106).

In general, scribe lines are spaces on the wafer between integrated circuit die. The scribe lines are large enough to allow separation of the integrated die by cutting, sawing, breaking, or other suitable technique, without damaging the integrated circuit die. In an exemplary embodiment, wafer 100 has a 300 mm diameter, integrated circuit die 102 are 21 mm×21 mm, which is less than the reticle size, scribe lines are 100 μm, and the area of the grid of integrated circuit die separated by scribe lines is 200 mm×200 mm. However, these dimensions are for illustration only and may vary with a target semiconductor fabrication process. In embodiments where a reticle includes multiple integrated circuit die (e.g., for a System-on-Chip (SoC) of a multi-product wafer (MPW), which may include intellectual property (IP) of different vendors), intra-reticle scribe lines are formed in addition to inter-reticle scribe lines. In an embodiment, intra-reticle scribe lines are used for low-cost prototype testing.

A technique for interconnecting integrated circuit die of a semiconductor substrate to achieve desired functionality or performance uses a jumper die that is vertically attached to adjacent integrated circuit die thereby coupling the adjacent die across a scribe line between the adjacent integrated circuit die. As referred to herein, a jumper die vertically attached to an integrated circuit die is attached to the integrated circuit die using interconnect in a vertical direction with respect to a surface of a substrate of the integrated circuit die (e.g., a front side of the integrated circuit die). The vertical interconnect may include conductive bumps, conductive pillars, hybrid bonding, or other suitable die-to-die or die-to-wafer interconnect structures known in the art. As a result of being vertically attached, a portion of the jumper die is stacked with (i.e., overlaps) a portion of the integrated circuit die.

Referring to FIG. 2, integrated circuit product 200 includes semiconductor substrate portion 202 which includes integrated circuit die 204 and integrated circuit die 206 formed using semiconductor manufacturing techniques known in the art. In at least one embodiment, integrated circuit die 204 and integrated circuit die 206 are homogenous die formed using the same single-die reticle set (e.g., IP of the same vendor) and scribe line 222 is an inter-reticle scribe line. In an embodiment, integrated circuit die 204 and integrated circuit die 206 are homogenous die or heterogeneous die, are formed using the same, multi-die reticle image, and scribe line 222 is an intra-reticle scribe line (e.g., of an MPW). Jumper die 208 includes jumper die interface 216 and jumper die interface 218, which provide external electrical interfaces (e.g., conductive pads), and interconnect electrically coupling jumper die interface 216 and jumper die interface 218.

In at least one embodiment, jumper die interface 216 and jumper die interface 218 are disposed at or near opposite edges of jumper die 208. The size of a jumper die and scribe lines may vary. In at least one embodiment, jumper die 208 is substantially smaller than integrated circuit die 204 and integrated circuit die 206 but is large enough for pick-and-place assembly techniques. In an exemplary embodiment, scribe line 222 is 100 μm wide and chiplet 210, jumper die 208, and chiplet 212 have dimensions of 2 mm×2 mm. In at least one embodiment, jumper die 208 is vertically attached to integrated circuit die 204 and integrated circuit die 206 using microbumps that are approximately 30 μm high and are directly attached to conductive pads of integrated circuit die 204 and integrated circuit die 206 using die-to-die or die-to-wafer attachment techniques known in the art. In embodiments that use hybrid bonding to vertically attach jumper die 208 to integrated circuit die 204 and integrated circuit die 206, the interconnect is less than 30 μm high and is directly attached to conductive pads of integrated circuit die 204 or integrated circuit die 206. However, these dimensions and vertical attachment techniques are for illustration only and may vary with target semiconductor manufacturing and packaging processes.

In general, jumper die 208 is a chiplet, i.e., a small, modular integrated circuit die that is designed to be combined with other integrated circuit die to form a larger, more complex SoC. Jumper die and chiplets are tested prior to assembly with integrated circuit die 204 and integrated circuit die 206. Jumper die 208 includes interconnect that electrically couples jumper die interface 216 and jumper die interface 218. The interconnect may be passive or active, as described further below and may be formed using integrated circuit manufacturing techniques that are well-known in the art. Integrated circuit die 204 and integrated circuit die 206 include integrated circuit die interface 220 and 224, respectively, and have pinouts that correspond to pinouts of jumper die interface 216 and jumper die interface 218, respectively. In at least one embodiment, a chiplet interface or jumper die interface is compliant with a predetermined die-to-die interconnection specification (e.g., Universal Chiplet Interconnect Express (UCIe), The Bunch of Wires (BoW), Advanced Interface Bus (AIB), Open High Bandwidth Interface (HBI), Optical Internetworking Forum (OIF) Extra Short Reach (XSR), or other suitable die-to-die interconnection specification).

In at least one embodiment, jumper die 208 is assembled face-to-face with integrated circuit die 204 and integrated circuit die 206. Jumper die interface 216 is stacked with (i.e., overlaps) integrated circuit die interface 220, and jumper die interface 218 is stacked with integrated circuit die interface 224. Jumper die 208 is vertically attached to integrated circuit die 204 and integrated circuit die 206 using any suitable face-to-face/flip-chip (i.e., F2F) die-to-die or die-to-wafer bonding technique known in the art. In at least one embodiment, microbumps 214 are attached to conductive pads of integrated circuit die interface 220 and other microbumps are attached to conductive pads of integrated circuit die interface 224. In an embodiment, microbumps 214 have a suitable pitch (e.g., 40 μm pitch with 20 μm-25 μm bump size and 15 μm spacing between adjacent bumps). In other embodiments, hybrid bonding, e.g., using dielectric bonds with closely spaced conductive pads, sintered vertical wire meshes, or other vertical attachment techniques that provide suitable connection pitch known in the art are used. In some embodiments, additional integrated circuit die (e.g., chiplet 210 and chiplet 212, which include memory, input/output structures (I/O), processing units, or other functional circuits) are attached to integrated circuit die 204 or integrated circuit die 206 to include additional functionality of integrated circuit product 200 as specified for a target application. In at least one embodiment, jumper die 208 also includes functional circuitry. In at least one embodiment, jumper die 208, chiplet 210, and chiplet 212 have standard sizes, are disposed in standardized placement sites, and are spaced by width w₂ from each other. In some embodiments, width w₂ is the same as width w₁, which is the width of scribe line 222. However, in other embodiments, width w₁ is different from width w₂.

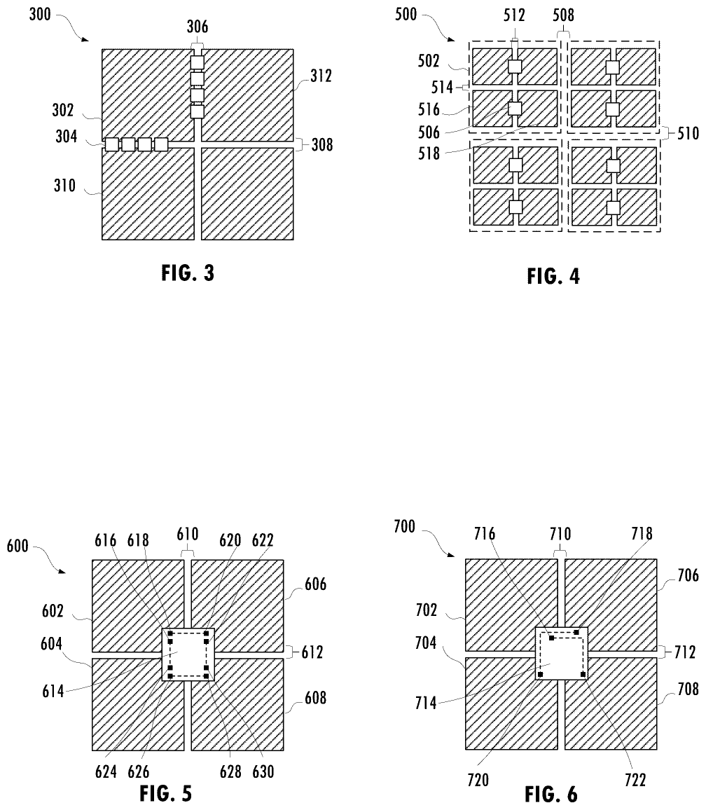

FIGS. 3-6 illustrate various configurations of jumper die coupling integrated circuit die across one or more scribe line of a semiconductor substrate. For example, in configuration 300, each instantiation of jumper die 304 has a predetermined unit size and is coupled to and stacked with a corresponding interface of integrated circuit die 302. Horizontally aligned jumper die are also coupled to an interface (e.g., conductive pads, not shown) of integrated circuit die 310 thereby electrically coupling integrated circuit die 302 to integrated circuit die 310 across horizontal scribe line 308. Vertically aligned jumper die are also coupled to an interface of integrated circuit die 312 thereby electrically coupling integrated circuit die 302 to integrated circuit die 312 across vertical scribe line 306.

Configuration 500 of FIG. 4 illustrates jumper die coupling integrated circuit die across intra-reticle scribe lines, e.g., in an MPW. In an exemplary embodiment, each reticle image includes subimages corresponding to a plurality of integrated circuit die and intra-reticle scribe lines. Pairs of those integrated circuit die are coupled across corresponding intra-reticle scribe lines using a jumper die to form a 3D integrated circuit product. For example, reticle image 502 includes four integrated circuit die (heterogeneous integrated circuit die or homogeneous integrated circuit die) and adjacent pairs of those integrated circuit die in reticle image 502 are coupled across vertical intra-reticle scribe line 512. Jumper die 506 couples integrated circuit die 516 to integrated circuit die 518 across vertical intra-reticle scribe line 512. Other configurations use additional jumper die to couple adjacent pairs of those integrated circuit die across horizontal intra-reticle scribe line 514 or across vertical inter-reticle scribe lines 508 or horizontal inter-reticle scribe lines 510.

Referring to FIG. 5, in at least one embodiment, a jumper die includes interconnect for coupling two or more integrated circuit die that are located at an intersection of scribe lines. For example, configuration 600 includes four-way jumper die 614, which includes jumper die interfaces 616, 618, 620, 622, 624, 626, 628, and 630 at or near corresponding corners of four-way jumper die 614 so that each jumper die interface overlaps an integrated circuit interface of a corresponding integrated circuit die. In an embodiment, four-way jumper die 614 couples integrated circuit die 602 to integrated circuit die 606 across scribe line 610 using jumper die interfaces 618 and 620, which are laterally interconnected, couples integrated circuit die 602 to integrated circuit die 604 across scribe line 612 using jumper die interfaces 616 and 624, which are laterally interconnected, couples integrated circuit die 606 to integrated circuit die 608 across scribe line 612 using jumper die interfaces 622 and 630, which are laterally interconnected, and couples integrated circuit die 608 to integrated circuit die 604 across scribe line 610 using jumper die interfaces 628 and 626, which are laterally interconnected. In an embodiment, four-way jumper die 614 includes at least eight jumper die interfaces at or near the corners of four-way jumper die 614 so that each jumper die interface of four-way jumper die 614 overlaps an integrated circuit interface of a corresponding integrated circuit die.

In at least one embodiment, a jumper die includes interconnect for coupling integrated circuit die disposed diagonally opposite to each other (i.e., catercorner integrated circuit die) at an intersection of scribe lines or more than two integrated circuit die. For example, in configuration 700 of FIG. 6, catercorner jumper die 714 couples integrated circuit die 702 to integrated circuit die 708, which are diagonally opposite each other, across scribe lines 710 and 712 using jumper die interfaces 716 and 722, which are laterally interconnected, and couples integrated circuit die 704 and integrated circuit die 706, which are diagonally opposite to each other across scribe lines 710 and 712 using jumper die interfaces 718 and 720, which are laterally interconnected. Other jumper die include interfaces and interconnect that provide different combinations of interconnections between two or more of the integrated circuit die disposed at the intersection of a horizontal scribe line and a vertical scribe line. In an embodiment, catercorner jumper die 714 includes at least four jumper die interfaces at or near the corners of catercorner jumper die 714 so that each jumper die interface overlaps a corresponding integrated circuit interface of an integrated circuit die. A library or product line of jumper die may include a jumper die sized and configured for each of the various combinations of interfaces and interconnect to provide different combinations of interconnections across one or more scribe line between two or more of the integrated circuit die disposed adjacent to a scribe line or at an intersection of a horizontal scribe line and a vertical scribe line.

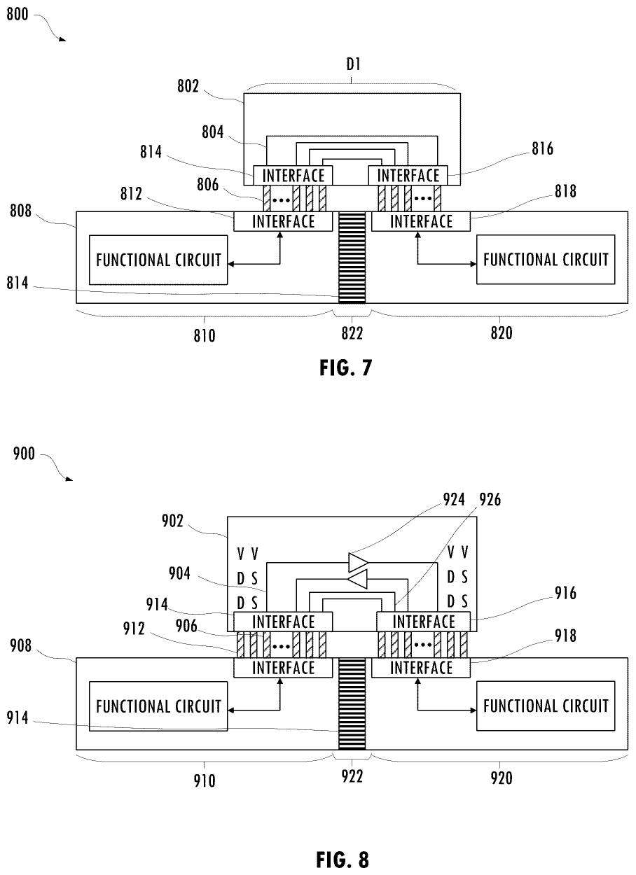

Referring to FIG. 7, in at least one embodiment, a jumper die includes only passive interconnect. For example, jumper die 802 includes jumper die interface 814 (e.g., conductive pads) that is passively coupled to jumper die interface 816. Therefore, jumper die interfaces 814 and 816 do not include power supply terminals. In general, passive interconnect includes conductive traces patterned in one or more conductive layers using integrated circuit manufacturing techniques and materials that are well-known in the art. In some embodiments, jumper die 802 includes no other circuitry. In at least one embodiment, the passive interconnect includes conductive traces that extend primarily in lateral directions with respect to a surface (e.g., a front side) of a semiconductor substrate of jumper die 802. Jumper die 802 couples integrated circuit die 810 and integrated circuit die 820 of integrated circuit product 800, which includes semiconductor substrate portion 808. Integrated circuit die 810 and integrated circuit die 820 may be homogenous die or heterogeneous die and scribe line 822 may be an inter-reticle scribe line or an inter-reticle scribe line, as discussed above. Jumper die 802 includes passive interconnect 804 (e.g., conductive traces) that couple jumper die interface 814 to jumper die interface 816. In an embodiment, jumper die interface 814 and jumper die interface 816 couple the passive interconnect to conductive pads for 3D connection to another integrated circuit die using connections that are vertical with respect to a surface (e.g., a front side including integrated circuit die) of semiconductor substrate portion 808. Interface 814 is stacked with interface 812 and interface 816 is stacked with integrated circuit die interface 818. In an embodiment, jumper die 802 is attached to integrated circuit die interface 812 and integrated circuit die interface 818 using microbumps 806 or other die-to-die or die-to-wafer interconnect known in the art. Integrated circuit die 810 includes integrated circuit die interface 812 and an associated functional circuit (e.g., central processing unit (CPU), graphics processing unit (GPU), digital signal processor (DSP), co-processor, memory, radio frequency (RF) communications interfaces, or other functional circuit) and integrated circuit die 820 includes integrated circuit die interface 818 and an associated functional circuit (e.g., CPU, GPU, DSP, co-processor, memory, RF communications interfaces, or other functional circuit). In an exemplary embodiment, scribe line 822 is 100 μm wide, jumper die 802 has dimensions of 2 mm×2 mm, and integrated circuit die 810 and integrated circuit die 820 have lateral dimensions with respect to the surface of the substrate that are less than or equal to dimensions of the reticle set used to manufacture those integrated circuit die. However, these dimensions are for illustration only and may vary with target semiconductor manufacturing and packaging processes.

Referring to FIG. 8, in at least one embodiment, a jumper die includes at least some active interconnect, i.e., interconnect including devices requiring power supplied by power supply terminals, or functional circuitry (not shown). In at least one embodiment, the jumper die includes a first interface circuit that is actively coupled to a second interface circuit and the first interface circuit, or the second interface circuit includes power supply terminals. For example, jumper die 902 includes buffers 924, which are active devices. Therefore, jumper die interface 914 or jumper die interface 916 includes power supply terminals (e.g., VDD and VSS) that provide power to buffers 924 via jumper die interface 914 and jumper die interface 916. The interconnect and any functional circuitry of jumper die 902 are formed using integrated circuit manufacturing and packaging techniques and materials that are known in the art.

Integrated circuit product 900 includes semiconductor substrate portion 908 which includes integrated circuit die 910 and integrated circuit die 920. Jumper die 902 couples integrated circuit die 910 and integrated circuit die 920. Integrated circuit die 910 and integrated circuit die 920 may be homogenous die or heterogeneous die and scribe line 922 may be an inter-reticle scribe line or an inter-reticle scribe line, as discussed above. Jumper die interface 914 and jumper die interface 916 provide an electrical interface that is coupled using active interconnect 904 (e.g., interconnect including buffers 924 for high-speed digital communications or other devices requiring power supplied by power supply terminals). In at least one embodiment, jumper die 902 includes other active circuitry coupled between jumper die interface 914 and jumper die interface 916, e.g., a power conversion circuit, an amplifier, a filter, other digital or analog circuitry or a combination thereof. Accordingly, jumper die interface 914 or jumper die interface 916 include power supply terminals for receiving power from integrated circuit die 910 or integrated circuit die 920, which receive power, e.g., from the backside of semiconductor substrate portion 908 using TSVs (not shown).

In at least one embodiment, jumper die 902 also includes passive interconnect (i.e., pass through interconnect 926) for low-speed analog signals. In an embodiment, jumper die interface 914 and jumper die interface 916 include conductive pads for 3D connection to another integrated circuit die. The 3D connections are vertical with respect to a surface of semiconductor substrate portion 908 thereby stacking at least a portion jumper die interface 914 and 916 with corresponding portions of other integrated circuit die. In an embodiment, jumper die 902 is vertically attached to integrated circuit die interface 912 and integrated circuit die interface 918 using microbumps 906 or other die-to-die or die-to-wafer interconnect. Integrated circuit die 910 and integrated circuit die 920 include integrated circuit die interface 912 and an associated functional circuit (e.g., CPU, GPU, DSP, co-processor, memory, RF communications interfaces, or other functional circuit) and integrated circuit die 920 includes integrated circuit die interface 918 and an associated functional circuit (e.g., CPU, GPU, DSP, co-processor, memory, RF communications interfaces, or other functional circuit), respectively. In an exemplary embodiment, scribe line 922 is 100 μm wide, jumper die 902 has dimensions of 2 mm×2 mm, and integrated circuit die 910 and integrated circuit die 920 have lateral dimensions with respect to the surface (e.g., the front side) of the substrate that are less than or equal to dimensions of the reticle set used to manufacture those integrated circuit die. However, these dimensions are for illustration only and may vary with target semiconductor fabrication processes.

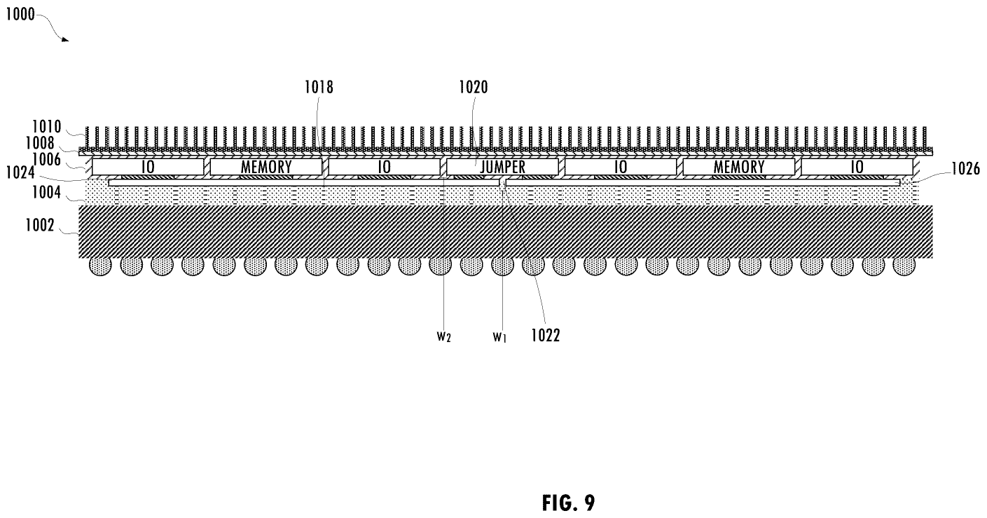

FIG. 9 illustrates an embodiment of a 3D integrated circuit product. Integrated circuit product 1000 includes jumper die 1020, which is vertically attached across scribe line 1022 of semiconductor substrate 1004 and interconnects integrated circuit die 1024 to integrated circuit die 1026 of semiconductor substrate 1004. Integrated circuit die 1024 and integrated circuit die 1026 may be homogenous die or heterogeneous die and scribe line 1022 may be an inter-reticle scribe line or an intra-reticle scribe line, as discussed above. Through silicon vias (TSVs) and conductive pillars 1018 couple integrated circuit die 1024 and integrated circuit die 1026 to I/O of package substrate 1002. Conductive bumps (not shown) couple the conductive pillars of semiconductor substrate 1004 to exposed conductors of package substrate 1002. In an embodiment, jumper die 1020 and I/O chiplets and memory chiplets are vertically attached to integrated circuit die 1024 and integrated circuit die 1026 using die-to-die or die-to-wafer connection techniques known in the art. In at least one embodiment, jumper die 1020 and the other chiplets are disposed in standardized placement sites and are spaced by width w₂ from each other. In some embodiments scribe line 1022 has width w₁, where width w₁ is the same as width w₂. However, in other embodiments, width w₁ is different from width w₂.

After being attached to integrated circuit die 1024 and integrated circuit die 1026, jumper die 1020 and the other chiplets are encapsulated, e.g., using mold compound in encapsulant layer 1006. Exemplary encapsulants include underfill material, mold compound material, or combination thereof. In general, the encapsulant fills gaps between the integrated circuit die to protect interconnect structures and bare die face. Encapsulation mechanically locks dissimilar materials together to reduce or eliminate differential in-plane movement so that interfaces move in harmony with joint integrity preserved. Thermal interface material (TIM) 1008 is applied between the surface of encapsulant layer 1006 and heat exchanger 1010 to increase thermal transfer efficiency. In at least one embodiment, TIM 1008 is a fluid (e.g., a non-curing polymeric matrix, a silicone-based fluid, or polysynthetic oil).

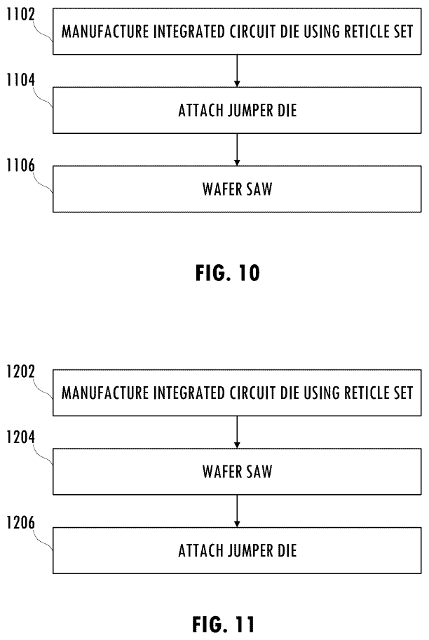

Referring to FIGS. 9 and 10, in at least one embodiment of an integrated circuit product using a jumper die for integrated circuit die stitching, integrated circuit die 1024 and integrated circuit die 1026 are manufactured using the same set of reticles and the same semiconductor substrate (1102). Prior to dicing the semiconductor substrate, jumper die 1020 and any other integrated circuit die (e.g., I/O and memory chiplets) are attached to integrated circuit die 1024 and integrated circuit die 1026 using any suitable face-to-face/flip-chip (i.e., F2F) die-to-die or die-to-wafer bonding technique (1104). After attaching jumper die 1020 and any other integrated circuit die to integrated circuit die 1024 and integrated circuit die 1026, semiconductor substrate 1004 (including integrated circuit die 1024 and integrated circuit die 1026) is diced from other integrated circuit die by cutting, sawing, breaking, or other suitable technique, without damaging the die (1106).

Referring to FIGS. 9 and 11, in other embodiments of an integrated circuit product, integrated circuit die integrated circuit die 1024 and integrated circuit die 1026 are manufactured using the same set of reticles and the same semiconductor substrate (1202). Before attaching jumper die 1020 and other integrated circuit die (e.g., I/O and memory chiplets) to integrated circuit die 1024 and integrated circuit die 1026, integrated circuit die 1024 and integrated circuit die 1026 are separated from other integrated circuit products by cutting, sawing, breaking, or other suitable technique, without damaging the integrated circuit die (1204). After dicing the semiconductor substrate, jumper die 1020 and other integrated circuit die (e.g., I/O and memory chiplets) are attached to integrated circuit die 1024 and integrated circuit die 1026 using any suitable face-to-face/flip-chip (i.e., F2F) die-to-die or die-to-wafer bonding technique (1206).

In addition to being applicable to 3D SoC and chip-scale package technologies, the techniques described in FIGS. 9 and 10 may be used in wafer-scale integration for building very large integrated circuits from an entire silicon wafer to produce a single wafer-scale product. In such embodiments, top and bottom packaging layers and solder bumps are attached to the integrated circuit die while the integrated circuit die are still part of a wafer. Note that manufacturing processes of FIGS. 9-11 are exemplary only and other sequences and types of manufacturing steps may be used to generate a 3D integrated circuit product using a jumper die for integrated circuit die stitching.

Thus, techniques for interconnecting integrated circuit die using a jumper die that is vertically attached to adjacent integrated circuit die thereby coupling adjacent die across a scribe line have been described. The techniques do not require reticle stitching, fan-out, or an interposer, which are expensive techniques, and the jumper die techniques reduce the need for specialized manufacturing processes from a manufacturing foundry. Therefore, integrated circuit die stitching using a jumper die reduces manufacturing cost, time-to-market, and reliance on a particular foundry for manufacturing associated 3D integrated circuit products, wafer-scale products, and MPW products.

The description of the invention set forth herein is illustrative and is not intended to limit the scope of the invention as set forth in the following claims. The terms “first,” “second,” “third,” and so forth, as used in the claims, unless otherwise clear by context, are to distinguish between different items in the claims and do not otherwise indicate or imply any order in time, location, or quality. For example, “a first received signal” and “a second received signal,” do not indicate or imply that the first received signal occurs in time before the second received signal. Variations and modifications of the embodiments disclosed herein may be made based on the description set forth herein, without departing from the scope of the invention as set forth in the following claims.

What is claimed is:

1. An integrated circuit product comprising:
a first integrated circuit die having a first die interface, the first integrated circuit die being formed using a semiconductor substrate;
a second integrated circuit die having a second die interface, the second integrated circuit die being formed using the semiconductor substrate;
a scribe line of a first surface of the semiconductor substrate, the first integrated circuit die being adjacent to the scribe line and the second integrated circuit die being adjacent to the scribe line; and
a jumper die coupled to the first die interface and coupled to the second die interface,
wherein the jumper die spans the scribe line, a first portion of the jumper die is stacked with a first portion of the first integrated circuit die, and a second portion of the jumper die is stacked with a first portion of the second integrated circuit die.

2. The integrated circuit product as recited in claim 1, wherein the scribe line is an inter-reticle scribe line.

3. The integrated circuit product as recited in claim 1, wherein the scribe line is an intra-reticle scribe line.

4. The integrated circuit product as recited in claim 1 further comprising:
an additional die coupled to the first integrated circuit die and stacked with the first integrated circuit die, the additional die being laterally adjacent to the jumper die with respect to the first surface of the semiconductor substrate,
wherein a space between the additional die and the jumper die has the same width as the scribe line.

5. The integrated circuit product as recited in claim 1 wherein the jumper die comprises:
a first jumper die interface corresponding to the first die interface;
a second jumper die interface corresponding to the second die interface; and
a lateral interconnect structure coupled between the first jumper die interface and the second jumper die interface.

6. The integrated circuit product as recited in claim 1, wherein a first conductive pad of a front side of the jumper die is connected to a corresponding conductive pad of a front side of the first integrated circuit die vertically with respect the front side of the first integrated circuit die and the front side of the jumper die using a microbump or a hybrid bond.

7. The integrated circuit product as recited in claim 1 wherein the first integrated circuit die is disposed diagonally opposite to the second integrated circuit die.

8. The integrated circuit product as recited in claim 1 further comprising:
at least one additional integrated circuit die adjacent to the first integrated circuit die or the second integrated circuit die and diagonally opposite to the other integrated circuit die of the first integrated circuit die and the second integrated circuit die; and
wherein a third portion of the jumper die is stacked with a first portion of the at least one additional integrated circuit die attached to a corresponding die interface of the at least one additional integrated circuit die and spans a second scribe line between the first integrated circuit die or the second integrated circuit die and the at least one additional integrated circuit die, and
wherein the second scribe line intersects the scribe line.

9. An integrated circuit product comprising:
a jumper die comprising:
a first jumper die interface;
a second jumper die interface; and
a lateral interconnect structure coupled between the first jumper die interface and the second jumper die interface.

10. The integrated circuit product as recited in claim 9 wherein the jumper die is configured to transmit a signal received from a first integrated circuit die via the first jumper die interface to a second integrated circuit die via the second jumper die interface across a scribe line of a semiconductor substrate used to form the first integrated circuit die and the second integrated circuit die.

11. The integrated circuit product as recited in claim 9 further comprising:
a first integrated circuit die; and
a second integrated circuit die, the first integrated circuit die and the second integrated circuit die being formed using a semiconductor substrate,
wherein the jumper die is stacked with a first corresponding die interface of the first integrated circuit die and stacked with a second corresponding die interface of the second integrated circuit die and the jumper die spans a scribe line of a first surface of the semiconductor substrate.

12. The integrated circuit product as recited in claim 11 further comprising:
an additional die stacked with the first integrated circuit die or the second integrated circuit die, the additional die being laterally adjacent to the jumper die with respect to the first surface of the semiconductor substrate,
wherein a space between the jumper die and the additional die has the same width as the scribe line.

13. The integrated circuit product as recited in claim 11, wherein the first jumper die interface includes a first conductive pad of a front side of the jumper die, the first conductive pad being connected to a corresponding conductive pad of a front side of the first integrated circuit die vertically with respect the front side of the first integrated circuit die using a microbump or a hybrid bond.

14. The integrated circuit product as recited in claim 9,
wherein the lateral interconnect structure comprises an active circuit, and
wherein the jumper die further comprises power supply terminals configured to provide power to the active circuit.

15. The integrated circuit product as recited in claim 9 wherein the lateral interconnect structure is passive interconnect.

16. The integrated circuit product as recited in claim 9 wherein the first jumper die interface is disposed at a first edge of the jumper die and the second jumper die interface is disposed at a second edge of the jumper die.

17. The integrated circuit product as recited in claim 9 wherein the first jumper die interface is disposed at a first corner of the jumper die and the second jumper die interface is disposed at a second corner of the jumper die.

18. A method for manufacturing a three-dimensional integrated circuit product, the method comprising:
vertically attaching a jumper die to a first die interface of a first integrated circuit die and a second die interface of a second integrated circuit die, the first integrated circuit die and the second integrated circuit die being formed using a semiconductor substrate, the first integrated circuit die being separated from the second integrated circuit die by a scribe line of a first surface of the semiconductor substrate, the jumper die spanning the scribe line and overlapping a first portion of the first integrated circuit die and overlapping a second portion of the second integrated circuit die.

19. The method as recited in claim 18 wherein the first integrated circuit die is adjacent to or diagonally opposite to the second integrated circuit die.

20. The method as recited in claim 18 further comprising:
manufacturing the first integrated circuit die and the second integrated circuit die using a first semiconductor substrate and an image of a reticle,
wherein the scribe line is an intra-reticle scribe line and the first integrated circuit die and the second integrated circuit die correspond to different locations within the image of the reticle.

21. The method as recited in claim 18 wherein vertically attaching comprises:
connecting vertically with respect a front side of the first integrated circuit die and a front side of the jumper die, a first conductive pad of the front side of the jumper die to a corresponding conductive pad of the front side of the first integrated circuit die, using a microbump or a hybrid bond.

22. The method as recited in claim 18 further comprising:
vertically attaching an additional die to an additional die interface of the first integrated circuit die, the additional die being separated from the jumper die by a space having the same width as the scribe line and being laterally adjacent to the jumper die with respect to the first surface of the semiconductor substrate.

23. The three-dimensional integrated circuit product formed by the method as recited in claim 18.
